(19) United States
(12) Patent Application Publication
(10) Pub. No.: US 2025/0389022 A1
(43) Pub. Date: Dec. 25, 2025

(54) HEATER MATERIALS TO PREVENT ARCING

(71) Applicant: Applied Materials, Inc., Santa Clara, CA (US)

(72) Inventors: Allison YAU, Cupertino, CA (US); Manoj Kumar JANA, San Jose, CA (US); Shichen FU, Santa Clara, CA (US); Wen-Shan LIN, San Jose, CA (US); Hang YU, Woodland, CA (US); Deenesh PADHI, Sunnyvale, CA (US); Jian LI, Fremont, CA (US); Ankit Atul GORATELA, San Jose, CA (US); Chidambara A. RAMALINGAM, Fremont, CA (US); Katherine WOO, Santa Clara, CA (US); Ganesh BALASUBRAMANIAN, Fremont, CA (US); Juan Carlos ROCHA-ALVAREZ, San Carlos, CA (US)

(21) Appl. No.: 18/751,693

(22) Filed: Jun. 24, 2024

(51) Int. Cl. C23C 16/458; H05B 3/12

(52) U.S. Cl. CPC C23C 16/4586; H05B 3/12; H01L 21/477

(57) ABSTRACT

Embodiments disclosed herein generally relate to a substrate support and a method for fabricating the same. The substrate support includes a heater having a high resistivity, such as a resistivity between 1E8 ohm-centimeter (ohm-cm) and 1E11. The resistivity of the heater is configured to prevent arcing.

### BACKGROUND

### Field

Embodiments of the present disclosure generally relate to components for substrate supports used in semiconductor device manufacturing. More specifically, embodiments described herein relate to a substrate support including a heater having a high resistivity, such as a resistivity between 1E8 ohm-centimeter (ohm-cm) and 1E11 ohm-cm at operating temperatures.

### Description of the Related Art

A substrate support is commonly used for holding a semiconductor substrate, for example, during deposition of a film layer on the substrate, etching of a film layer on the substrate, implanting ions into the substrate, and other processes. An electrostatic chuck disposed within or on the substrate support can chuck the substrate thereto by creating an attractive force between the substrate and the substrate support. A chucking voltage is applied by one or more electrodes in the electrostatic chuck to induce oppositely polarized charges in the substrate and the electrodes. The opposite charges pull the substrate and the electrostatic chuck/substrate support together, thus fixing the substrate in place.

Many current substrate processing techniques utilize high processing temperatures (e.g., 550° C. and higher), which often causes the substrate to bow. To counteract the bowing of the substrate at higher temperatures, the chucking voltage applied to the substrate can be increased. However, increasing the chucking voltage, along with the higher processing temperature, can result in greater leakage current, which increases the likelihood of electrical arcing between the substrate support and other components of the substrate processing chamber. Consequently, when arcing occurs during processing, it may result in damage to the substrate processing chamber and components thereof.

Thus, there is a need for an improved devices for preventing arcing during substrate processing at higher temperatures.

### SUMMARY

Embodiments disclosed herein generally relate to a substrate support and a method for fabricating the substrate support. The substrate support including a heater formed from materials which increase the resistivity of the heater.

One exemplary substrate support includes a heater having a high resistivity, such as a resistivity between 1E8 ohm-centimeter (ohm-cm) and 1E11 ohm-cm, wherein the resistivity of the heater is configured to prevent arcing. The heater is formed from an aluminum (Al) containing material such as aluminum nitride (AlN), or one or more of AlN, aluminum oxide (AlO), aluminum oxynitride (AlON), aluminum silicon nitride (AlSiN), aluminum silicate (Al₂SiO₅), or aluminum gallium (AlG).

One exemplary method for fabricating a substrate support includes forming a heater having a high resistivity, such as a resistivity between 1E8 ohm-cm and 1E11 ohm-cm, wherein the resistivity of the heater is configured to prevent arcing.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of scope, and may admit to other equally effective embodiments.

FIG. 1 illustrates a schematic cross-sectional view of a substrate processing chamber having a substrate support therein, according to embodiments.

FIG. 2 illustrates a schematic cross-sectional view of the processing chamber of FIG. 1 showing a substrate disposed on the substrate support during processing thereof, according to embodiments.

FIG. 3 illustrates an enlarged cross-sectional view of the substrate support and the substrate shown in FIG. 2, according to embodiments.

FIG. 4A-4B are graphs depicting differences in operating characteristics and arcing events experienced by heaters formed from different materials, according to embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments disclosed herein generally relate to components for substrate supports for use in semiconductor device manufacturing. More particularly, embodiments described herein relate to a heater having a high resistivity for preventing arcing, such as a resistivity between 1E8 ohm-centimeter (ohm-cm) and 1E11 ohm-cm. Heaters having a greater resistivity also exhibit various other improvements in performance over conventional heaters without such electrical characteristics.

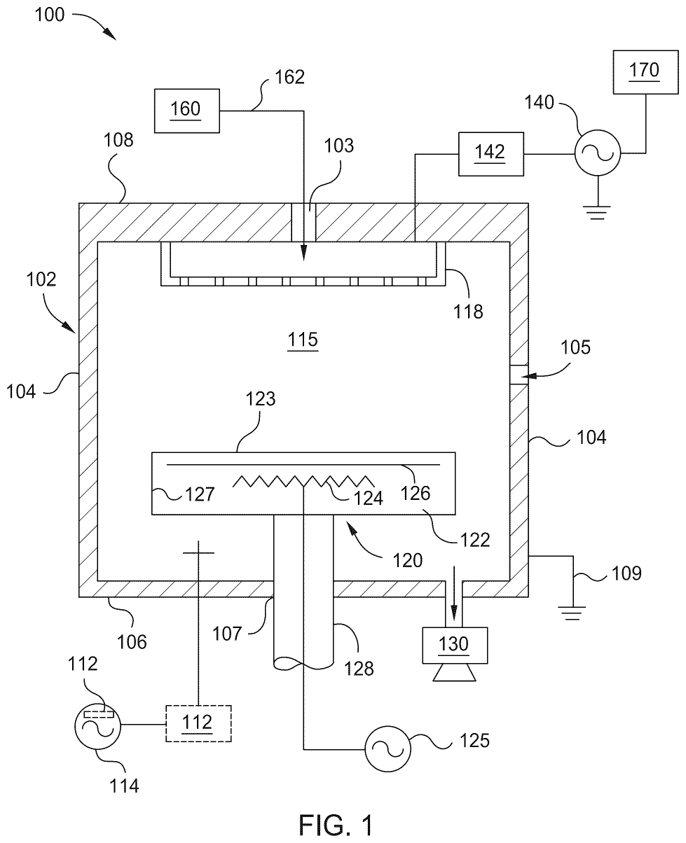

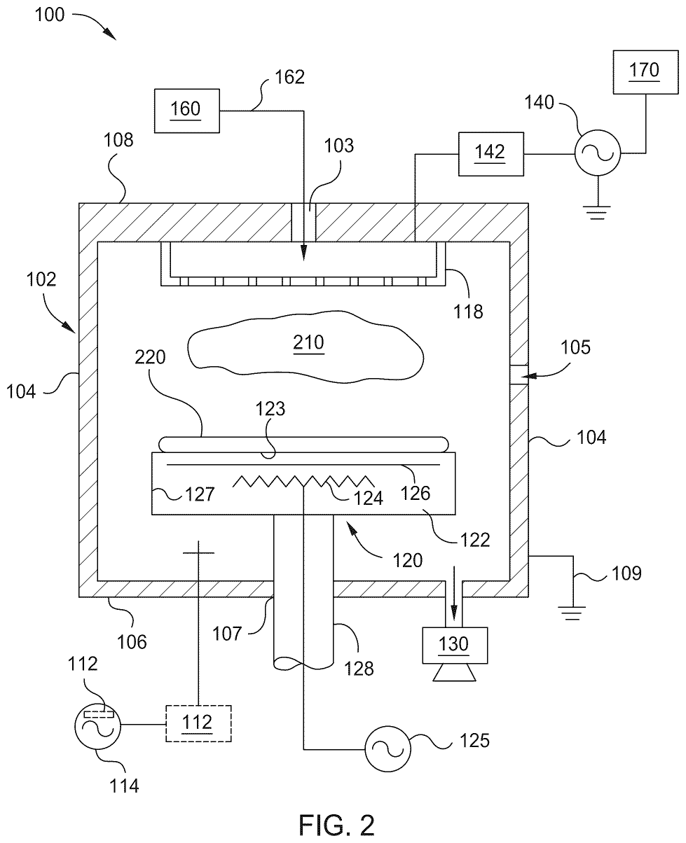

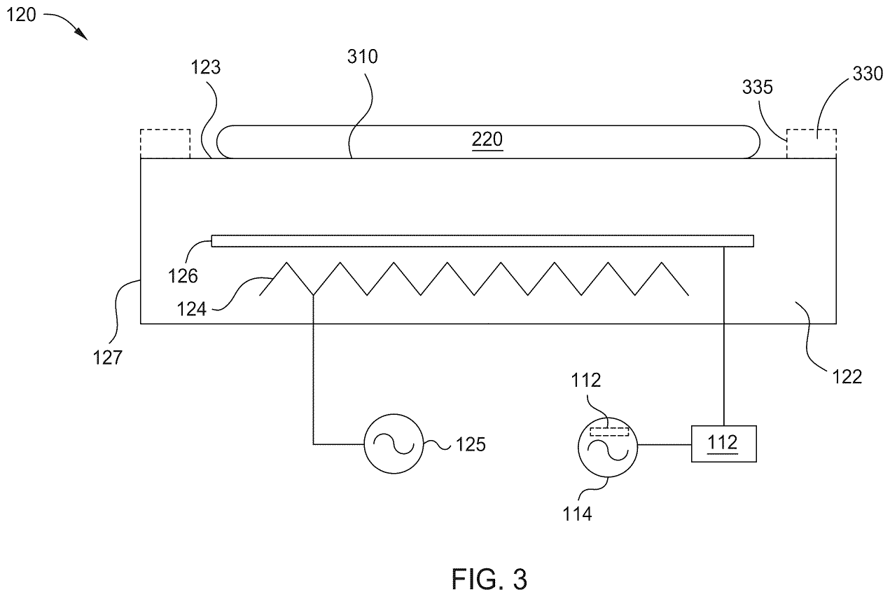

FIG. 1 illustrates a schematic cross-sectional view of a substrate processing chamber 100 having a substrate support 120 therein. FIG. 2 illustrates a schematic cross-sectional view of the processing chamber 100 of FIG. 1 with a substrate 220 disposed on the substrate support 120 during processing thereof. FIG. 3 illustrates an enlarged cross-sectional view of the substrate support 120 and the substrate 220 shown in FIG. 2. Accordingly, FIGS. 1, 2, and 3 are described together herein for clarity purposes.

The processing chamber 100 may be a chemical vapor deposition (CVD) chamber as shown, or other suitable plasma processing chamber. Examples of a processing chamber 100 that may be adapted to benefit from the disclosure include plasma-enhanced chemical vapor deposition (PECVD) chambers, such as but not limited to the CENTURA® apparatus, the PRODUCER® apparatus, the PRODUCER® GT apparatus, the PRODUCER® XP Precision™ apparatus, the PRODUCER® SE™ apparatus, and the TESSERACT® apparatus, which are available from Applied Materials, Inc., Santa Clara, Calif. It is contemplated that processing chambers from other manufacturers may also be adapted to benefit from the embodiments described herein. Although FIG. 1 described herein is illustrative of a PECVD chamber, the processing chamber 100 should not be construed or interpreted as limiting the scope of the embodiments described herein. The embodiments described herein can be equally applied to apparatus utilized for physical vapor deposition (PVD), etching, implanting, annealing, and plasma-treating materials on semiconductor substrates, among others.

As illustrated in FIG. 1, the processing chamber 100, shown schematically, includes a chamber body 102. The chamber body 102 has sidewalls 104, a bottom wall 106, and a chamber cover 108. The sidewalls 104, the bottom wall 106, and the cover 108 may be formed from conductive materials, such as aluminum, stainless steel, or alloys and combinations thereof. The sidewalls 104 and the bottom wall 106 are coupled to an electrical ground 109 when the processing chamber 100 is a plasma processing chamber. The chamber cover 108, the sidewalls 104, and the bottom wall 106 define a processing volume 115 therein. The sidewalls 104 include a substrate transfer port 105 to facilitate transfer of the substrate 220 into and out of the processing volume 115. The substrate transfer port 105 may be coupled to a transfer chamber and/or other chambers of a substrate processing system.

The dimensions of the chamber body 102 and related components of the processing chamber 100 are not limited and generally are proportionally larger than the size of the substrate 220 to be processed therein. The substrate 220 may be sized to have a diameter of 200 millimeters (mm) or less, 300 mm, and 450 mm or larger depending upon the desired implementation.

A gas panel 160 is fluidly connected by a conduit 162 to the processing volume 115 to provide one or more precursor gases or other process gases to the processing chamber 100. The conduit 162 is connected to an opening 103 through the chamber cover 108. A pump 130 is fluidly connected to the processing volume 115 to pump out the process gases and to maintain vacuum conditions within the processing volume 115 during substrate processing. The pump 130 may be a conventional roughing pump, roots blower, turbo pump, or other similar device that is adapted control the pressure in the processing volume 115 to a desired level.

A showerhead 118 is coupled to the chamber cover 108 and located above the substrate support 120 in the processing volume 115. The showerhead 118 is configured to introduce one or more precursor gases into the processing volume 115 of the processing chamber 100. The showerhead 118 also functions as an electrode for coupling RF power to the process gases introduced into the processing volume 115. The process gases from the gas panel 160 enter the processing volume 115 through the showerhead 118.

As illustrated in FIG. 2, an RF power source 140 is coupled to the showerhead 118 through an impedance matching circuit 142. The RF power source 140 is configured to provide the power necessary for striking and sustaining plasma 210 formed from gases within the processing volume 115. The operation of the RF power source 140 is controlled by a controller 170 that also controls the operation of other components in the processing chamber 100. Although the RF power source 140 is shown as being a top feed RF power source (i.e., disposed at above the processing chamber 100), the RF power source 140 may also be a bottom feed RF power source (i.e., disposed below the processing chamber 100).

The substrate support 120 is disposed within the processing volume 115. The substrate support 120 is supported on a hollow stem 128 and includes a support body 122 coupled to the stem 128. The stem 128 is connected to an opening 107 through the bottom wall 106 sealed by, for example, a flexible bellows. The support body 122 is formed from one or more dielectric materials, for example a ceramic material, such as aluminum nitride (AlN) among other suitable materials. The substrate support 120 has a top surface 123 and a side surface 127.

The support body 122 includes a heater 124 embedded therein. The heater 124 is coupled to a power source 125. The heater 124 may be a resistive heating element, an inductive heating element, or other suitable heater. The heater 124 is configured to heat the substrate 220 during processing to a temperature between about 100° C. (degrees Celsius) and about 800° C. The substrate 220 may also be actively cooled, such as by flowing a coolant through cooling channels therein. By actively balancing the heat input from the heater 124 and the cooling of the coolant, the temperature of the substrate support 120 and the substrate 220 placed thereon can be closely controlled. Further, the support body 122 may be cylindrical, rectangular, or other similar shape.

The heater 124 is formed from a material which provides the heater 124 with a high resistivity at operating temperatures, such as a resistivity between 1E8 ohm-cm and 1E11 ohm-cm at temperatures between 300° C. and 800° C. (e.g., 325° C. and 775° C., 350° C. and 750° C., 375° C. and 725° C., or 400° C. and 700° C.). For example, the heater 124 is formed from an aluminum (Al) containing material. The aluminum containing material comprises aluminum nitride (AlN), or one or more of AlN, aluminum oxide (AlO), aluminum oxynitride (AlON), aluminum silicon nitride (AlSiN), aluminum silicate (Al₂SiO₅), or aluminum gallium (AlG). The aluminum containing material of the heater 124 is doped with magnesium (Mg) or another dopant. In some embodiments, the dopant is premixed with the main materials (e.g., the aluminum containing material) of the heater 124 before sintering, the sintering performed according to standard sintering techniques. As an example, a concentration of the magnesium makes up no more than 10% (e.g., no more than 8%, 6%, 4%, or 2%) of a weight of the heater 124. Aluminum containing material that is doped with magnesium may sometimes be referred to herein as an “Mg-doped aluminum containing material”.

An electrostatic chuck 126 is embedded within the support body 122 of the substrate support 120. The electrostatic chuck 126 comprises one or more electrodes for electrostatically chucking the substrate 220 disposed on the substrate support 120 to the substrate support 120 during processing of the substrate in the processing chamber 100. The electrostatic chuck 126 is connected to a power source 114 through an isolation transformer 112 disposed between the power source 114 and the electrostatic chuck 126. The isolation transformer 112 may be part of the power source 114, or be separate from the power source 114, as shown by the dashed lines in FIG. 1. The power source 114 is configured to apply a chucking voltage between about 50 V_{DC} and about 2000 V_{DC} (e.g., between about 100 V_{DC} and 1900 V_{DC}, 200 V_{DC} and 1800 V_{DC}, 300 V_{DC} and 1700 V_{DC}, or 400 V_{DC} and 1600 V_{DC}) to the electrostatic chuck 126 to chuck the substrate 220. The power source 114 may communicate with a controller configured to control the operation of the electrostatic chuck 126 by selecting the current value supplied to the electrostatic chuck 126 for chucking and de-chucking of the substrate 220.

Note that, although described as separate components above, in certain embodiments, the heater 124 is integrated with or within the electrostatic chuck 126. Further, although the electrostatic chuck 126 is described as a component of the substrate support 120 above, in certain embodiments, the substrate support 120 may be an electrostatic chuck, while in other embodiments, the electrostatic chuck 126 is disposed on the substrate support 120.

Although not shown, a temperature sensor, such as but not limited to a thermocouple, may be connected to the support body 122 to measure the temperature of the substrate support 120. The temperature sensor is configured to communicate a signal indicative of the temperature of the support body 122 to a temperature controller which provides a control signal to the power source 125 to change the power supplied to the heater, or change the flow rate, temperature, or both of the coolant, when the heat input or loss related thereto changes.

As illustrated in FIG. 3, the substrate 220 is disposed on the top surface 123 of the support body 122, and a backside 310 of the substrate 220 is in contact with the top surface 123 of the support body 122. The top surface 123 may optionally include an outer rim (or lip) 330 extending upwards from the top surface 123, surrounding the substrate 220. The rim 330 may have a thickness between about 0.5 mm and about 2 mm, such as about 1 mm to about 1.3 mm, such as 1 mm. An inner wall 335 of the rim may be slanted or angled inwards towards the top surface 123. The substrate 220 may be positioned on the top surface 123 such that there is a gap between an outer edge of the substrate 220 and the inner wall 335 of the rim 330 on the top surface 123.

When the substrate 220 is processed at higher temperatures such as, for example, greater than 500° C., 600°° C., or 700° C., the substrate 220 may begin to bow. The substrate 220 may also begin to bow with more deposition, such that as the CVD process continues, the substrate 220 may experience more bowing due to film stress. In other words, the backside 310 of the substrate 220 may begin to at least partially separate, or move away from the top surface 123 of the support body 122. Consequently, when the substrate 220 bows, it may result in a loss of power and/or deposition of non-uniform films.

To prevent the substrate 220 from bowing, the electrostatic chuck 126 chucks the substrate 220 by applying an electrical force which holds the substrate 220 down during processing. In other words, the electrical force is applied to the substrate 220 to maintain substantially complete contact between the backside 310 of the substrate 220 and the top surface 123 of the support body 122. By maintaining contact between the backside 310 of the substrate 220 and the top surface 123 of the support body 122, heat and process induced bowing of the substrate 220 is mitigated. However, processing at higher temperatures often requires chucking the substrate 220 at higher voltages such as, for example, voltages greater than 700 V_{DC}, 1000 V_{DC}, or 1500 V_{DC}. Processing the substrate 220 at greater voltages often leads to a higher leakage current. As a result of increased leakage current, arcing between the substrate support 120 and other components of the chamber 100 is more likely to occur, which may potentially damage the chamber 100.

However, using the high resistivity heater 124 helps reduce leakage current at the substrate support 120. As an example, the heater 124 has a resistivity that is at least five times greater than conventional heaters made of other ceramic materials. For example, the resistivity of the heater 124 is between 1E8 ohm-cm and 1E11 ohm-cm (e.g., between 1E9 ohm-cm and 1E10 ohm-cm). The heater 124 may demonstrate such higher resistivity when the heater 124 is formed from an Mg-doped aluminum containing material, or other similar material. As such, an arcing margin of the heater 124 is more impactful at higher processing temperatures. In other words, increasing the resistivity will therefore have a bigger impact for arcing margins at higher temperatures. It is further contemplated that the resistivity of the heater 124 may be tailored to further improve the arcing margin, or achieve a desired arcing margin.

The higher resistivity of the heater 124 allows for a reduction in leakage current at the substrate support 120 because the substrate support 120 is able to maintain the charge applied by the electrostatic chuck 126. Further, chucking at higher voltages may also be improved by the reduction in leakage current because the heater 124 may be able to better hold charges. For example, in comparison to other heaters, a bowed substrate can be chucked at a lower chucking voltage with the heater 124. As such, the heater 124 helps mitigate (or prevent) arcing between the substrate support 120 and other components of the chamber 100, which therefore reduces the likelihood of damage being caused to the substrate support 120 and/or other components of the chamber 100.

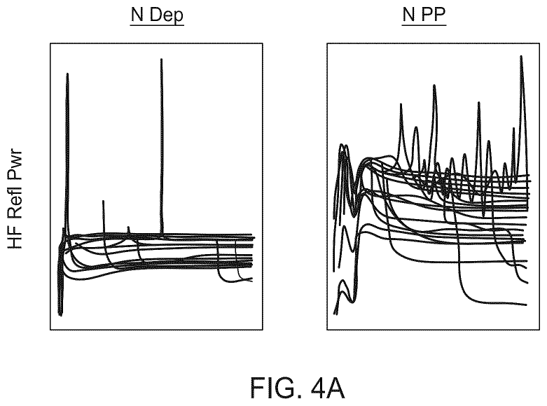

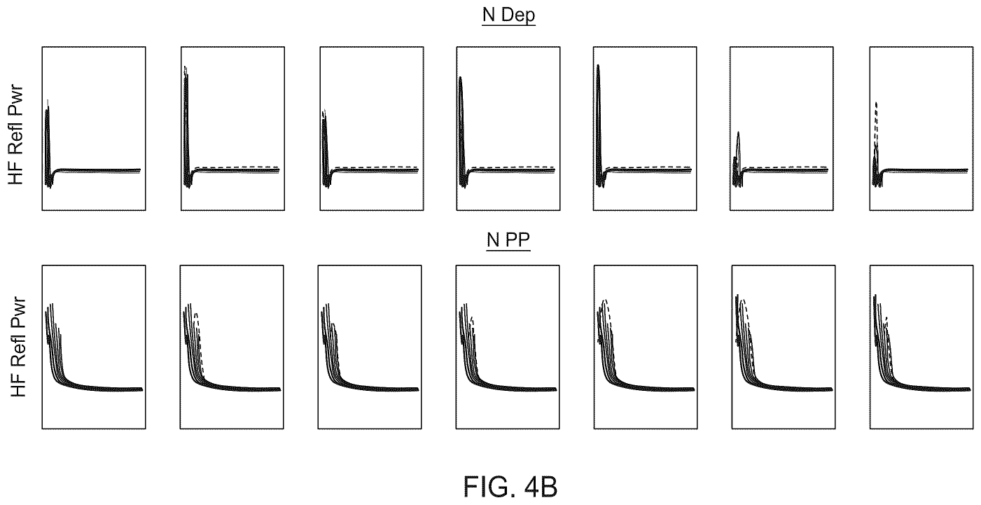

FIG. 4A-4B are graphs depicting differences in operating characteristics and arcing events experienced by heaters formed from different materials.

FIG. 4A includes graphs depicting operating characteristics for a heater formed from conventional materials such as, for example, heaters that are not formed from an Mg-doped aluminum containing material. The x-axis of the graphs represents time and the y-axis represents High Frequency (HF) Reflected Power. Traces in the graphs of FIG. 4A depict arcing events (shown by spikes in the traces) experienced by the heater while processing a substrate with, for example, a chucking voltage of ±900V_{DC} and a chamber temperature of 650° C. In these conditions, the heater demonstrates high plasma instability and experiences a plurality of arcing events.

FIG. 4B includes graphs depicting operating characteristics for a high resistivity heater (e.g., heater 124). The x-axis of the graphs represents time and the y-axis represents HF Reflected Power. Traces in the graphs of FIG. 4B depict a lack of arcing events (shown by a lack of spikes in the traces) experienced by the heater 124 while processing a substrate with, for example, a chucking voltage of ±1400 V_{DC} and a chamber temperature of 650° C. In these conditions, the heater 124 demonstrates greater plasma stability than the heater described with reference to FIG. 4A, and does not experience a plurality of arcing events.

The processes and logic flows described in this specification can be performed by one or more programmable processors executing one or more computer programs to perform functions by operating on input data and generating output. The processes and logic flows can also be performed by, and apparatus can also be implemented as, special purpose logic circuitry, e.g., an FPGA (field programmable gate array) or an ASIC (application specific integrated circuit).

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but is to be accorded the full scope consistent with the language of the claims, wherein reference to an element in the singular is not intended to mean “one and only one” unless specifically so stated, but rather “one or more.” Unless specifically stated otherwise, the term “some” refers to one or more. All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S.C. § 112(f) unless the element is expressly recited using the phrase “means for” or, in the case of a method claim, the element is recited using the phrase “step for.”

While various examples of the invention have been described above, it should be understood that they have been presented by way of example only, and not by way of limitation. Likewise, the various diagrams may depict an example architectural or other configuration for the disclosure, which is done to aid in understanding the features and functionality that can be included in the disclosure. The disclosure is not restricted to the illustrated example architectures or configurations, but can be implemented using a variety of alternative architectures and configurations. Additionally, although the disclosure is described above in terms of various example examples and aspects, it should be understood that the various features and functionality described in one or more of the individual examples are not limited in their applicability to the particular example with which they are described. They instead can be applied, alone or in some combination, to one or more of the other examples of the disclosure, whether or not such examples are described, and whether or not such features are presented as being a part of a described example. Thus the breadth and scope of the present disclosure should not be limited by any of the above-described example examples.

All references cited herein are incorporated herein by reference in their entirety. To the extent publications and patents or patent applications incorporated by reference contradict the disclosure contained in the specification, the specification is intended to supersede and/or take precedence over any such contradictory material.

Unless otherwise defined, all terms (including technical and scientific terms) are to be given their ordinary and customary meaning to a person of ordinary skill in the art, and are not to be limited to a special or customized meaning unless expressly so defined herein.

Terms and phrases used in this application, and variations thereof, especially in the appended claims, unless otherwise expressly stated, should be construed as open ended as opposed to limiting. As examples of the foregoing, the term ‘including’ should be read to mean ‘including, without limitation,’ ‘including but not limited to,’ or the like; the term ‘including’ as used herein is synonymous with ‘including,’ ‘containing,’ or ‘characterized by,’ and is inclusive or open-ended and does not exclude additional, unrecited elements or method steps; the term ‘having’ should be interpreted as ‘having at least;’ the term ‘includes’ should be interpreted as ‘includes but is not limited to;’ the term ‘example’ is used to provide example instances of the item in discussion, not an exhaustive or limiting list thereof; adjectives such as ‘known’, ‘normal’, ‘standard’, and terms of similar meaning should not be construed as limiting the item described to a given time period or to an item available as of a given time, but instead should be read to encompass known, normal, or standard technologies that may be available or known now or at any time in the future; and use of terms like ‘preferably,’ ‘preferred,’ ‘desired,’ or ‘desirable,’ and words of similar meaning should not be understood as implying that certain features are critical, essential, or even important to the structure or function of the invention, but instead as merely intended to highlight alternative or additional features that may or may not be utilized in a particular example of the invention. Likewise, a group of items linked with the conjunction ‘and’ should not be read as requiring that each and every one of those items be present in the grouping, but rather should be read as ‘and/or’ unless expressly stated otherwise. Similarly, a group of items linked with the conjunction ‘or’ should not be read as requiring mutual exclusivity among that group, but rather should be read as ‘and/or’ unless expressly stated otherwise.

The term “including as used herein is synonymous with “including,” “containing,” or “characterized by” and is inclusive or open-ended and does not exclude additional, unrecited elements or method steps.

All numbers expressing quantities of ingredients, reaction conditions, and so forth used in the specification are to be understood as being modified in all instances by the term ‘about.’ Accordingly, unless indicated to the contrary, the numerical parameters set forth herein are approximations that may vary depending upon the desired properties sought to be obtained. At the very least, and not as an attempt to limit the application of the doctrine of equivalents to the scope of any claims in any application claiming priority to the present application, each numerical parameter should be construed in light of the number of significant digits and ordinary rounding approaches.

Furthermore, although the foregoing has been described in some detail by way of illustrations and examples for purposes of clarity and understanding, it is apparent to those skilled in the art that certain changes and modifications may be practiced. Therefore, the description and examples should not be construed as limiting the scope of the invention to the specific examples and examples described herein, but rather to also cover all modification and alternatives coming with the true scope and spirit of the invention.

What is claimed is:

1. A substrate support disposed within a processing volume, comprising:
a heater having a resistivity between 1E8 ohm-centimeter (ohm-cm) and 1E11 ohm-cm,
wherein the resistivity of the heater is configured to prevent arcing.

2. The substrate support of claim 1, wherein the heater is formed from an aluminum (Al) containing material.

3. The substrate support of claim 2, wherein the aluminum containing material comprises aluminum nitride (AlN).

4. The substrate support of claim 2, wherein the aluminum containing material is one or more of AlN, aluminum oxide (AlO), aluminum oxynitride (AlON), aluminum silicon nitride (AlSiN), aluminum silicate (Al₂SiO₅), or aluminum gallium (AlG).

5. The substrate support of claim 1, wherein the heater is doped with magnesium (Mg).

6. The substrate support of claim 5, wherein a concentration of the magnesium makes up no more than 10% of a weight of the heater.

7. The substrate support of claim 1, wherein the resistivity of the heater is tailored to exhibit a desired arcing margin.

8. The substrate support of claim 1, wherein the heater is configured to reduce leakage current.

9. A method of fabricating a substrate support, comprising:
forming a heater having a resistivity between 1E8 ohm-centimeter (ohm-cm) and 1E11 ohm-cm,
wherein the resistivity of the heater is configured to prevent arcing.

10. The method of fabricating the substrate support of claim 9, wherein the heater is formed from an aluminum (Al) containing material.

11. The method of fabricating the substrate support of claim 10, wherein the aluminum containing material comprises aluminum nitride (AlN).

12. The method of fabricating the substrate support of claim 10, wherein the aluminum containing material is one or more of AlN, aluminum oxide (AlO), aluminum oxynitride (AlON), aluminum silicon nitride (AlSiN), aluminum silicate (Al₂SiO₅), or aluminum gallium (AlG).

13. The method of fabricating the substrate support of claim 9, wherein the heater is doped with magnesium (Mg).

14. The method of fabricating the substrate support of claim 13, wherein a concentration of the magnesium makes up no more than 10% of a weight of the heater.

15. The method of fabricating the substrate support of claim 9, wherein the resistivity of the heater is tailored to exhibit a desired arcing margin.

16. The method of fabricating the substrate support of claim 9, wherein the heater is configured to reduce leakage current.
